(19) United States
(12) Patent Application Publication
(10) Pub. No.: US 2025/0324658 A1
(43) Pub. Date: Oct. 16, 2025

(54) SEMICONDUCTOR DEVICE

(71) Applicants: DENSO CORPORATION, Kariya-city (JP); TOYOTA JIDOSHA KABUSHIKI KAISHA, Toyota-shi (JP); MIRISE Technologies Corporation, Nisshin-shi (JP)

(72) Inventors: KOJI ITO, Nisshin-shi (JP); RYOTA SUZUKI, Nisshin-shi (JP)

(21) Appl. No.: 18/984,007

(22) Filed: Dec. 17, 2024

(30) Foreign Application Priority Data
Apr. 16, 2024 (JP) 2024-066069

(51) Int. Cl. H10D 30/66; H10D 62/10

(52) U.S. Cl. CPC H10D 30/665; H10D 62/106; H10D 62/126; H10D 30/668

(57) ABSTRACT

A semiconductor device has a superjunction layer and guard ring regions in a termination portion of a semiconductor substrate. The guard ring regions have a first guard ring region including at least an outermost guard ring region, and a second guard ring region located on an inner side of the first guard ring region. The first guard ring region is spaced apart from second conductivity type columns of the superjunction layer. The second guard ring region is in contact with the second conductivity type columns of the superjunction layer.

### CROSS REFERENCE TO RELATED APPLICATION

This application is based on Japanese Patent Application No. 2024-066069 filed on Apr. 16, 2024, the disclosure of which is incorporated herein by reference.

### TECHNICAL FIELD

The present disclosure relates to a semiconductor device.

### BACKGROUND

A semiconductor substrate of a semiconductor device has an active portion and a termination portion located around the active portion. A gate structure is provided in the active portion, and a termination breakdown structure is provided in the termination portion. A semiconductor device has a superjunction layer (hereinafter referred to as SJ layer) and plural guard ring regions as a voltage withstanding structure of the termination portion.

### SUMMARY

According to an aspect of the present disclosure, a semiconductor device includes a semiconductor substrate having an active portion and a termination portion located around the active portion. The termination portion has: a lower drift region of a first conductivity type; a superjunction layer provided on the lower drift region, in which first conductivity type columns and second conductivity type columns are alternately arranged in at least one direction; an upper drift region of a first conductivity type provided on the superjunction layer; and guard ring regions of a second conductivity type surrounded by the upper drift region and extended around the active portion. The guard ring regions may have a first guard ring region including at least an outermost guard ring region, and a second guard ring region including a guard ring region located on an inner side of the first guard ring region. The first guard ring region is spaced apart from the second conductivity type columns of the superjunction layer. The second guard ring region is in contact with the second conductivity type columns of the superjunction layer.

### BRIEF DESCRIPTION OF DRAWINGS

FIG. 1 is a plan view showing a positional relationship between an active portion and a termination portion defined in a semiconductor substrate.

FIG. 2 is a schematic cross-sectional view of a semiconductor device according to a first embodiment, taken along line II-II in FIG. 1.

FIG. 3 is a schematic perspective view of an active portion of a semiconductor layer.

FIG. 4 is a schematic cross-sectional view of a semiconductor device according to a second embodiment, corresponding to line II-II in FIG. 1.

FIG. 5 is a schematic cross-sectional view of a semiconductor device according to a third embodiment, corresponding to line II-II in FIG. 1.

### DESCRIPTION OF EMBODIMENTS

A semiconductor substrate of a semiconductor device has an active portion and a termination portion located around the active portion. A gate structure is provided in the active portion, and a termination breakdown structure is provided in the termination portion. The semiconductor device has a superjunction layer (hereinafter referred to as SJ layer) and guard ring regions as a voltage withstanding structure of the termination portion.

The SJ layer and the guard ring region are disposed apart from each other in the thickness direction of the semiconductor substrate, with the drift region therebetween. For example, if the impurity concentration in the drift region is increased in order to reduce the on-resistance, an electric field will concentrate at the pn junction between the guard ring region and the drift region, which may result in a decrease in the breakdown voltage of the semiconductor device. The present specification provides a technique for suppressing a decrease in breakdown voltage in a semiconductor device having a superjunction layer and guard ring regions in a termination portion.

According to an aspect of the present disclosure, a semiconductor device includes a semiconductor substrate having an active portion and a termination portion located around the active portion. The termination portion has: a lower drift region of a first conductivity type; a superjunction layer provided on the lower drift region, in which first conductivity type columns and second conductivity type columns are alternately arranged in at least one direction; an upper drift region of a first conductivity type provided on the superjunction layer; and guard ring regions of a second conductivity type surrounded by the upper drift region and extended all around the active portion. The guard ring regions may have a first guard ring region including at least an outermost guard ring region, and a second guard ring region including a guard ring region located on an inner side of the first guard ring region. The first guard ring region is spaced apart from the second conductivity type columns of the superjunction layer. The second guard ring region is in contact with the second conductivity type columns of the superjunction layer.

In the semiconductor device, the second guard ring region provided on the inner periphery of the guard ring regions is formed deep enough to contact the second conductivity type column of the superjunction layer. This reduces the electric field concentration at the pn junction between the second guard ring region and the upper drift region. In case where all of the guard ring regions are formed deep enough to contact the second conductivity type column of the superjunction layer, when a small voltage is applied to the semiconductor substrate, the outermost guard ring region would not be depleted. In this case, there would be concerns about electric field concentration at the pn junction between a side surface of the outermost guard ring region and the upper drift region. In the semiconductor device, the first guard ring region including the outermost guard ring region has a floating potential, due to the location formed away from the second conductivity type column of the superjunction layer. This reduces the electric field concentration at the pn junction between the side surface of the outermost guard ring region and the upper drift region. In this manner, in the semiconductor device, the electric field concentration is alleviated throughout the guard ring regions, so that a decrease in the breakdown voltage is suppressed.

Hereinafter, a semiconductor device to which the technology disclosed in this specification is applied will be described with reference to the drawings. In the drawings, only some of common components may be denoted by reference numerals for the purpose of clarity of illustration. In respective embodiments, common components are denoted by common reference numerals, and descriptions thereof will be omitted.

### First Embodiment

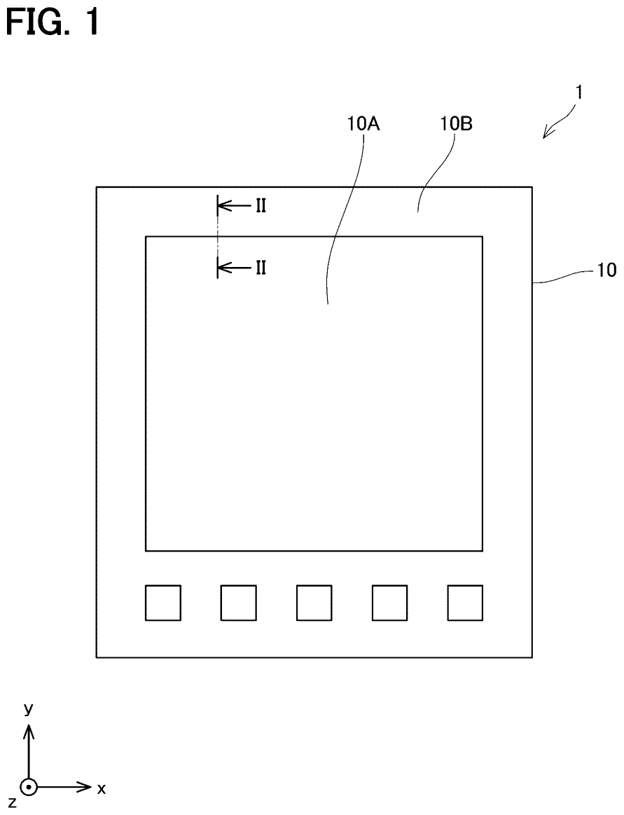

As shown in FIGS. 1 to 3, a semiconductor device 1 is a type of power device called a MOSFET, and is formed using a semiconductor substrate 10. The material of the semiconductor substrate 10 is not limited, but may be, for example, a wide gap semiconductor. The wide band gap semiconductor is not limited, but may be, for example, a silicon carbide (SiC) and nitride semiconductor. The semiconductor device 1 may be a power device called an insulated gate bipolar transistor (IGBT).

As shown in FIG. 1, the semiconductor substrate 10 has an active portion 10A and a termination portion 10B when viewed in a direction perpendicular to the main surface of the semiconductor substrate 10 (hereinafter referred to as “in a plan view”). The active portion 10A is a region defined on the inner area of the semiconductor substrate 10, in which a switching structure is formed, as described later. The termination portion 10B is a region defined on the outer area of the semiconductor substrate 10, that is, around the active portion 10A, in which a termination breakdown voltage structure is formed, as described later.

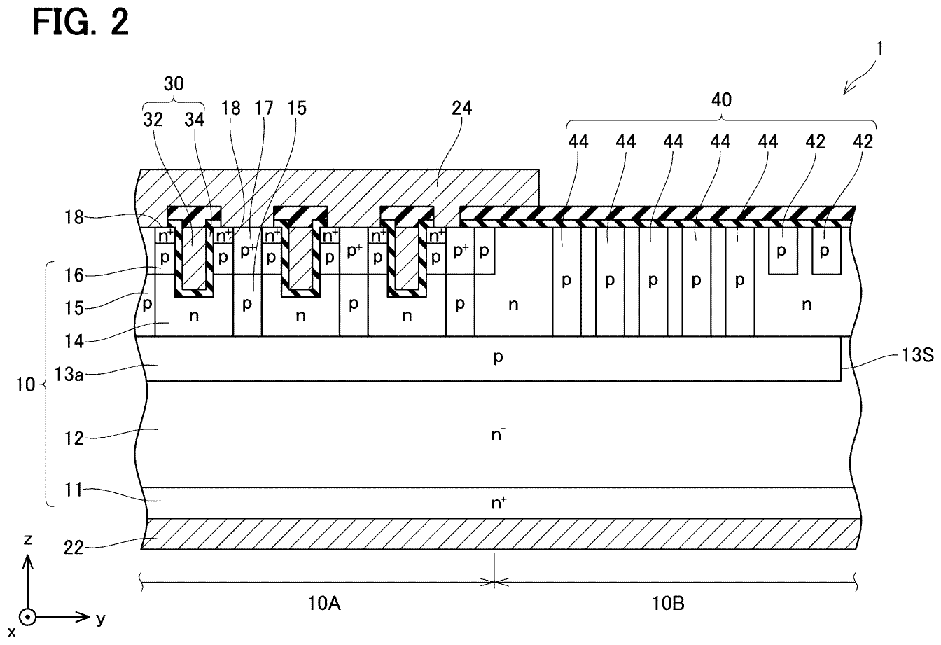

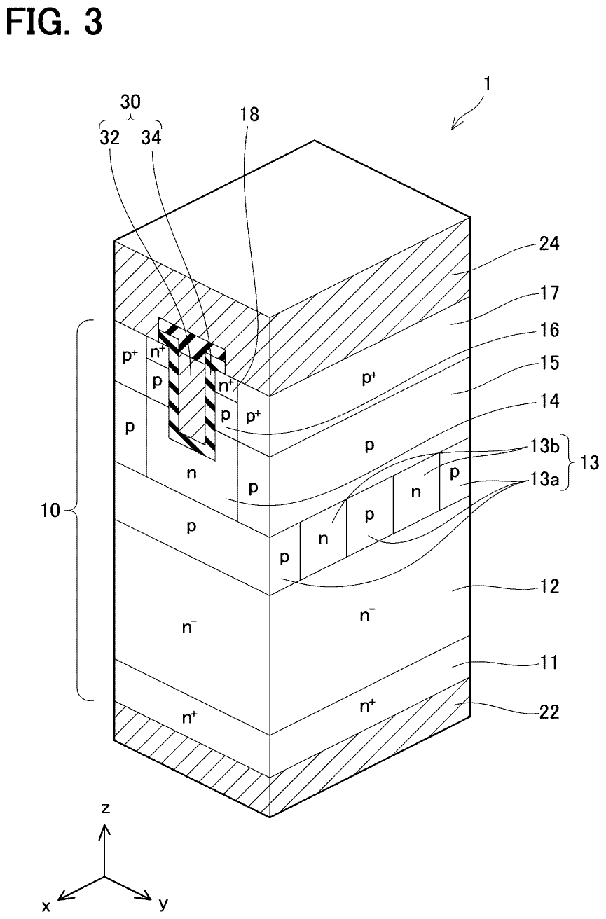

As shown in FIGS. 2 and 3, the semiconductor device 1 includes a drain electrode 22, a source electrode 24, and plural trench gates 30 in the semiconductor substrate 10. The semiconductor substrate 10 has a drain region 11, a lower drift region 12, a superjunction layer 13 (hereinafter referred to as SJ layer 13), an upper drift region 14, a deep P region 15, a body region 16, a contact region 17, and a source region 18. The trench gates 30 are provided in the active portion 10A, through which current flows between the drain electrode 22 and the source electrode 24 when the semiconductor device 1 is turned on. The guard ring regions 40 are provided in the termination portion 10B, which causes a depletion layer to extend outward when the semiconductor device 1 is turned off. In this embodiment, the periphery of the body region 16 defines a boundary between the active portion 10A and the termination portion 10B.

The drain electrode 22 is provided to cover the lower surface of the semiconductor substrate 10. The drain electrode 22 is disposed in both the active portion 10A and the termination portion 10B, and is in contact with the entire lower surface of the semiconductor substrate 10.

The source electrode 24 is provided to cover the upper surface of the semiconductor substrate 10. The source electrode 24 is disposed over substantially the entire active portion 10A, and is in contact with the upper surface of the semiconductor substrate 10 exposed through an opening of the interlayer insulating film formed on the upper surface of the semiconductor substrate 10.

The drain region 11 is an n-type region including n-type impurities at high concentration. The drain region 11 is provided in both the active portion 10A and the termination portion 10B, and is disposed at a position exposed at the lower surface of the semiconductor substrate 10. The drain region 11 is in ohmic contact with the drain electrode 22.

The lower drift region 12 is provided on the drain region 11 and is an n-type region having a lower n-type impurity concentration than the drain region 11. Another semiconductor region may be provided between the lower drift region 12 and the drain region 11. The lower drift region 12 is provided in both the active portion 10A and the termination portion 10B. The lower drift region 12 may be formed by growing a crystal from the surface of the drain region 11 using, for example, a crystal growth technique. The lower drift region 12 is called a drift region together with the upper drift region 14 which will be described later.

The SJ layer 13 is provided on the lower drift region 12 and has plural p-type columns 13a and plural n-type columns 13b. Another semiconductor region may be provided between the SJ layer 13 and the lower drift region 12. Each of the p-type columns 13a is a p-type region containing p-type impurities. Each of the n-type columns 13b is an n-type region containing n-type impurities. The SJ layer 13 is provided in both the active portion 10A and the termination portion 10B. A periphery 13S of the SJ layer 13 does not reach the side surface of the semiconductor substrate 10. The side surface of the SJ layer 13 constituting the periphery 13S is in contact with the drift region. An n-type field stop region (not shown) fixed to the drain potential is formed at a position exposed at the upper surface of the semiconductor substrate 10 outside the periphery 13S of the SJ layer 13.

Each of the p-type columns 13a and each of the n-type columns 13b extend along at least one direction (in this embodiment, the y direction, which is perpendicular to the longitudinal direction of the trench gate 30) in a plane view of the semiconductor substrate 10. The p-type columns 13a and the n-type columns 13b are alternately and repeatedly arranged in a direction (the x direction in this embodiment), parallel to the longitudinal direction of the trench gate 30. The width and impurity concentration of the p-type columns 13a and the n-type columns 13b are adjusted to achieve charge balance. The p-type columns 13a and the n-type columns 13b may be formed by introducing p-type impurities into a portion of the lower drift region 12 using, for example, an ion implantation technique.

The upper drift region 14 is provided on the SJ layer 13 and is an n-type region containing n-type impurities. Another semiconductor region may be provided between the upper drift region 14 and the SJ layer 13. The upper drift region 14 is provided in both the active portion 10A and the termination portion 10B. The concentration of n-type impurities in the upper drift region 14 may be the same as the concentration of n-type impurities in the lower drift region 12, or may be higher than the concentration of n-type impurities in the lower drift region 12. The concentration of n-type impurities in the upper drift region 14 may be different between the active portion 10A and the termination portion 10B, or may be the same. In this example, the concentration of n-type impurities in the upper drift region 14 is higher than the concentration of n-type impurities in the lower drift region 12, and is the same between the active portion 10A and the termination portion 10B. When the concentration of n-type impurities in the upper drift region 14 is higher than the concentration of n-type impurities in the lower drift region 12, the on-resistance of the semiconductor device 1 decreases. When the concentration of n-type impurities in the upper drift region 14 is the same between the active portion 10A and the termination portion 10B, the upper drift region 14 can be formed in each of the active portion 10A and the termination portion 10B at the same time in the same process. The upper drift region 14 is in contact with the bottom surface and the lower portion of the side surface of the trench gates 30. The upper drift region 14 is in contact with the n-type columns 13b of the SJ layer 13. The upper drift region 14 may be formed, for example, by growing an epitaxial layer from the upper surface of the SJ layer 13 using a crystal growth technique, and then introducing n-type impurities into at least a portion of the epitaxial layer using an ion implantation technique.

The deep P region 15 is a p-type region containing p-type impurities. The deep P region 15 is provided in the active portion 10A and penetrates the upper drift region 14. The upper end of the deep P region 15 is in contact with the body region 16 or the contact region 17, and the lower end of the deep P region 15 is in contact with the p-type column 13a of the SJ layer 13. As a result, the potential of the p-type column 13a of the SJ layer 13 is fixed to the source potential. The deep P region 15 extends along at least one direction (the x direction, in this embodiment, parallel to the longitudinal direction of the trench gate 30) when the semiconductor substrate 10 is viewed in the plan view. The deep P region 15 may be formed by introducing p-type impurities into a portion of the upper drift region 14 using, for example, an ion implantation technique.

The body region 16 is a p-type region containing p-type impurities. The body region 16 is provided in the active portion 10A and disposed on the upper drift region 14. Another semiconductor region may be provided between the body region 16 and the upper drift region 14. The body region 16 is in contact with the side surface of the trench gate 30 and separates the upper drift region 14 and the source regions 18 from each other. The body region 16 may be formed by introducing p-type impurities into a portion of the upper drift region 14 using, for example, an ion implantation technique.

The contact region 17 is provided in contact with the body region 16 and is a p-type region that contains a higher concentration of p-type impurities than the body region 16. The contact region 17 is provided in the active portion 10A and is disposed at a position exposed at the upper surface of the semiconductor substrate 10. The contact region 17 is exposed from an opening of an interlayer insulating film formed on the upper surface of the semiconductor substrate 10, and is in ohmic contact with the source electrode 24. The contact region 17 may be formed by introducing p-type impurities into a portion of the upper drift region 14 using, for example, an ion implantation technique.

The source region 18 is provided on the body region 16 and is an n-type region containing a high concentration of n-type impurities. Another semiconductor region may be provided between the source region 18 and the body region 16. The source region 18 is provided in the active portion 10A and is disposed at a position exposed at the upper surface of the semiconductor substrate 10. The source region 18 is exposed from an opening of an interlayer insulating film formed on the upper surface of the semiconductor substrate 10, and is in ohmic contact with the source electrode 24. The source region 18 is in contact with the upper portion of the side surface of the trench gate 30. The source region 18 may be formed by introducing n-type impurities into a portion of the upper drift region 14 using, for example, an ion implantation technique.

Each of the trench gates 30 is provided in the active portion 10A, and extends from the upper surface of the semiconductor substrate 10 through the source region 18 and the body region 16 to reach the upper drift region 14. Each of the trench gates 30 extends along at least one direction (the x direction in this embodiment) when the semiconductor substrate 10 is viewed in the plan view. The trench gates 30 are repeatedly arranged at intervals in a direction (the y direction in this embodiment) perpendicular to the longitudinal direction. In this manner, the trench gates 30 are arranged in a stripe pattern when the semiconductor substrate 10 is viewed in the plan view. The arrangement of the trench gates 30 is not limited to the stripe shape and may be other layouts. Each of the trench gates 30 includes a gate electrode 32 and a gate insulating film 34. The gate electrode 32 is insulated from the upper drift region 14, the body region 16, and the source region 18 by the gate insulating film 34, and is insulated from the source electrode 24 by the interlayer insulating film.

In this way, in the active portion 10A, a switching structure is formed by the drain electrode 22, the drain region 11, the lower drift region 12, the SJ layer 13, the upper drift region 14, the deep P region 15, the body region 16, the contact region 17, the source region 18, the source electrode 24, and the trench gate 30.

As shown in FIG. 2, the semiconductor substrate 10 further includes plural guard ring regions 40 provided in the termination portion 10B. For example, a total of seven guard ring regions 40 are illustrated, but the number is not limited. Each of the guard ring regions 40 is surrounded by the upper drift region 14, and is a p-type region that contains p-type impurities. Each of the guard ring regions 40 is provided at a position exposed at the upper surface of the semiconductor substrate 10, and extends around the periphery of the active portion 10A along the termination portion 10B. The guard ring regions 40 are repeatedly arranged at intervals in an in-out direction (defined by connecting the center of the active portion 10A and the termination portion 10B) when the semiconductor substrate 10 is viewed in the plan view. A part of the upper drift region 14 is disposed between the guard ring regions 40 adjacent to each other. The guard ring regions 40 may be formed by introducing p-type impurities into a portion of the upper drift region 14 using, for example, an ion implantation technique. The guard ring regions 40 are an example of a termination breakdown withstand structure.

The guard ring regions 40 include multiple first guard ring regions 42 and multiple second guard ring regions 44 formed deeper than the first guard ring regions 42.

The first guard ring regions 42 include at least an outermost guard ring region 40. For example, two guard ring regions 40 from the outermost periphery correspond to the first guard ring regions 42, but the number is not limited. Each of the first guard ring regions 42 is separated from the p-type column 13a of the SJ layer 13 and has a floating potential. The impurity concentration and dimension of each of the first guard ring regions 42 are appropriately designed according to the electrical characteristics desired for the semiconductor device 1.

The second guard ring regions 44 include one or more guard ring regions 40 arranged on the inner side of the first guard ring region 42. Each of the second guard ring regions 44 is in contact with the p-type column 13a of the SJ layer 13, and its potential is fixed to the source potential. The impurity concentration and dimension of each of the second guard ring regions 44 are appropriately designed according to the electrical characteristics desired for the semiconductor device 1.

Next, the operation of the semiconductor device 1 will be described. When a voltage equal to or higher than a gate threshold voltage is applied to the gate electrode 32 in a state where a voltage is applied between the drain electrode 22 and the source electrode 24 such that a potential of the drain electrode 22 is higher than a potential of the source electrode 24, a channel is formed at a portion of the body region 16 adjacent to the gate insulating film 34. Electrons supplied from the source region 18 flow into the upper drift region 14 through the channel. The electrons that have flowed into the upper drift region 14 flow to the drain region 11 via the n-type columns 13b of the SJ layer 13 and the lower drift region 12. As a result, conduction occurs between the drain electrode 22 and the source electrode 24, and the semiconductor device 1 is turned on.

When a voltage lower than the gate threshold voltage is applied to the gate electrode 32, the channel disappears and the semiconductor device 1 is turned off. When the semiconductor device 1 is turned off, the p-type columns 13a and n-type columns 13b of the SJ layer 13 are depleted, thereby mitigating the electric field concentration in the termination portion 10B.

In order to understand the characteristics of the semiconductor device 1 of this embodiment, a comparative example will be considered in which none of the guard ring regions 40 reaches the p-type columns 13a of the SJ layer 13. In such a comparative example, for example, if the impurity concentration of the upper drift region 14 is increased in order to reduce the on-resistance, an electric field will be concentrated at the pn junction between the guard ring region 40 and the upper drift region 14, which may result in a decrease in the breakdown voltage of the semiconductor device.

In contrast, in the semiconductor device 1 of this embodiment, the second guard ring region 44 provided along the inner periphery of the guard ring regions 40 is formed deep enough to contact the p-type column 13a of the SJ layer 13. This promotes depletion of the second guard ring region 44 and the upper drift region 14, and reduces electric field concentration at the pn junction between the second guard ring region 44 and the upper drift region 14. Furthermore, if all of the guard ring regions 40 are formed deep enough to contact the p-type columns 13a of the SJ layer 13, when a small voltage is applied to the semiconductor substrate 10, the outermost guard ring region 40 would not be depleted, and there would be a concern of electric field concentration at the p-n junction between the side surface of the outermost guard ring region 40 and the upper drift region 14. In the semiconductor device 1 of this embodiment, the first guard ring region 42 including the outermost guard ring region 40 is formed away from the p-type columns 13a of the SJ layer 13 and is at a floating potential. This reduces electric field concentration at the pn junction between the side surface of the outermost guard ring region 40 and the upper drift region 14. In this manner, in the semiconductor device 1 of the present embodiment, the electric field concentration is alleviated throughout the multiple guard ring regions 40, and therefore a decrease in breakdown voltage is suppressed.

### Second Embodiment

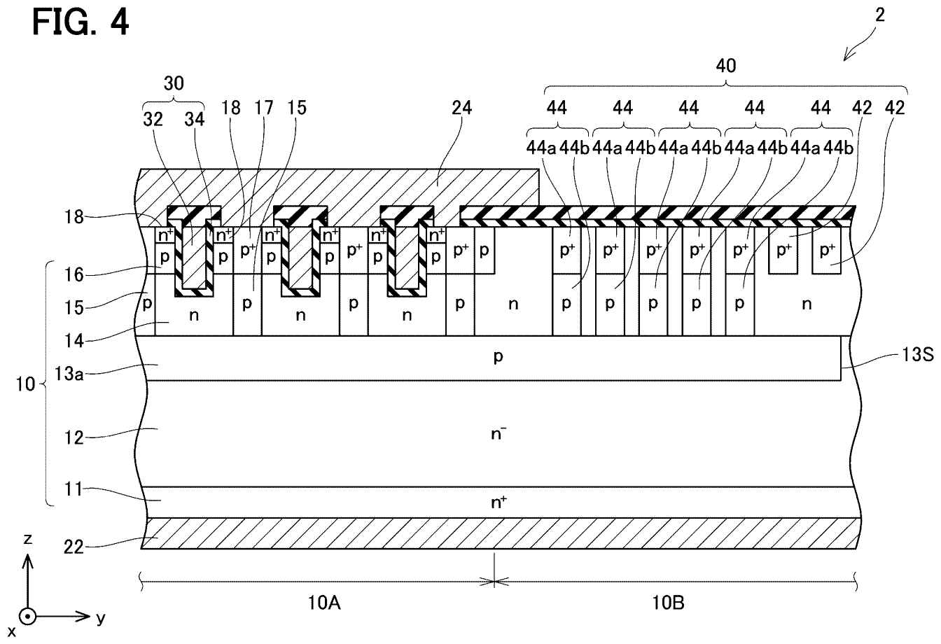

As shown in FIG. 4, in a semiconductor device 2 of a second embodiment, each of the second guard ring regions 44 has an upper guard ring portion 44a and a lower guard ring portion 44b. The upper guard ring portion 44a is formed in the same depth range as the first guard ring region 42. The lower guard ring portion 44b is formed at least in the depth range between the upper guard ring portion 44a and the p-type column 13a of the SJ layer 13. In this embodiment, the upper guard ring portion 44a of the second guard ring region 44 and the first guard ring region 42 can be formed simultaneously in the same process. Therefore, the manufacturing cost of the semiconductor device 2 can be reduced.

Furthermore, in the semiconductor device 2 of the second embodiment, the upper guard ring portion 44a of the second guard ring region 44 and the first guard ring region 42 are formed in the same depth range as the contact region 17. This allows the upper guard ring portion 44a of the second guard ring region 44, the first guard ring region 42, and the contact region 17 to be formed simultaneously in the same process. Further, the lower guard ring portion 44b of the second guard ring region 44 and the deep P region 15 are formed in the same depth range. This allows the lower guard ring portion 44b of the second guard ring region 44 and the deep P region 15 to be formed simultaneously in the same process. Therefore, the manufacturing cost of the semiconductor device 2 can be reduced.

### Third Embodiment

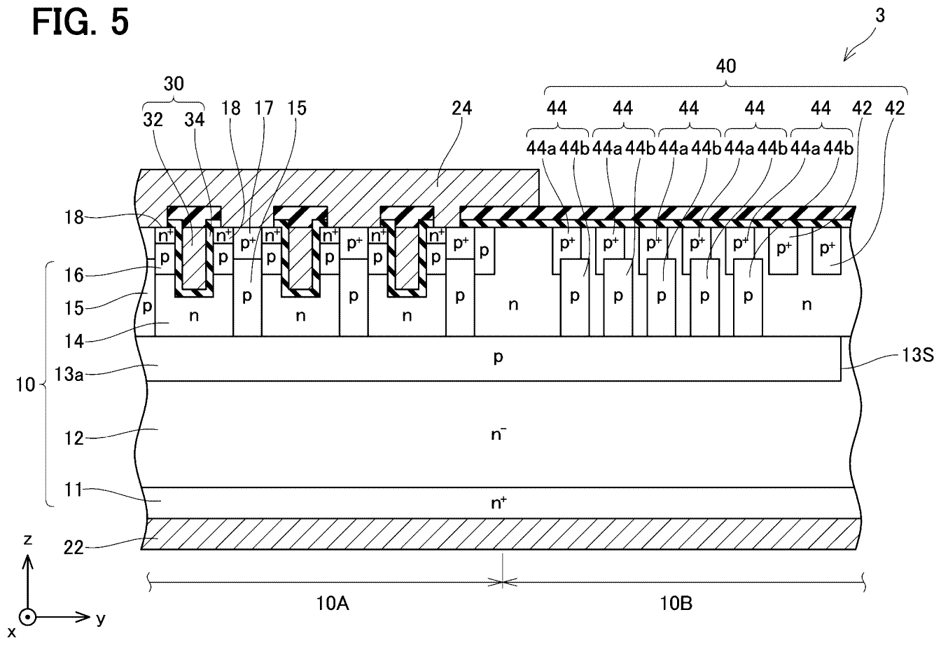

As shown in FIG. 5, in a semiconductor device 3 of a third embodiment, in the second guard ring region 44, the upper end of the lower guard ring portion 44b and the lower end of the upper guard ring portion 44a are formed to overlap each other. Furthermore, the lower guard ring portion 44b and the upper guard ring portion 44a are offset in the in-out direction connecting the active portion 10A and the termination portion 10B. Therefore, in the overlap of the lower guard ring portion 44b and the upper guard ring portion 44a, the distance between the side surface of the lower guard ring portion 44b and the side surface of the upper guard ring portion 44a becomes shorter. With this configuration, the minimum distance between the lower guard ring portion 44b and the upper guard ring portion 44a can be made smaller than the minimum processing dimension. As a result, even if the concentration of n-type impurities in the upper drift region 14 is high, the depletion layer can be made to progress satisfactorily from the inner periphery toward the outer periphery when the semiconductor device 1 is turned off. In this manner, the structure of the multiple guard ring regions 40 included in the semiconductor device 3 is useful when the concentration of n-type impurities in the upper drift region 14 is high.

Although the embodiments have been described in detail above, these are merely examples and do not limit the scope of present disclosure. The techniques described in claims include various modifications of the specific examples illustrated above. The technical elements described in the present specification or the drawings exhibit technical usefulness alone or in various combinations, and are not limited to the combinations described in the claims at the time of filing. In addition, the techniques illustrated in the present specification or drawings achieve plural objectives at the same time, and achieving one of the objectives itself has technical usefulness.

What is claimed is:

1. A semiconductor device comprising:
a semiconductor substrate having an active portion and a termination portion located around the active portion, wherein
the termination portion has
a lower drift region of a first conductivity type,
a superjunction layer provided on the lower drift region, in which first conductivity type columns and second conductivity type columns are alternately formed in at least one direction,
an upper drift region of a first conductivity type provided on the superjunction layer, and
a plurality of guard ring regions of a second conductivity type that are surrounded by the upper drift region and extended around the active portion,
the plurality of guard ring regions include
a first guard ring region including at least an outermost guard ring region of the plurality of guard ring regions, and
a second guard ring region including a guard ring region disposed on an inner side of the first guard ring region,
the first guard ring region is spaced apart from the second conductivity type column of the superjunction layer, and
the second guard ring region is in contact with the second conductivity type column of the superjunction layer.

2. The semiconductor device according to claim 1, wherein
the second guard ring region has:
an upper guard ring portion formed in the same depth range as the first guard ring region; and
a lower guard ring portion formed at least in a depth range between the upper guard ring portion and the second conductivity type column of the superjunction layer.

3. The semiconductor device according to claim 2, wherein
an impurity concentration of the upper drift region is higher than an impurity concentration of the lower drift region,
an upper end of the lower guard ring portion and a lower end of the upper guard ring portion overlap with each other, and
the lower guard ring portion and the upper guard ring portion are offset from each other in a direction connecting the active portion and the termination portion.

4. The semiconductor device according to claim 3, wherein
the lower drift region, the superjunction layer, and the upper drift region are further provided in the active portion, and
the upper drift region has the same impurity concentration between the termination portion and the active portion.

5. The semiconductor device according to claim 1, wherein the semiconductor substrate is a wide gap semiconductor.
